(19) United States
(12) Patent Application Publication
(10) Pub. No.: US 2005/0270847 A1
(43) Pub. Date: Dec. 8, 2005

(54) Battery

(75) Inventors: Motohiro Miyoshi, Mukou-shi (JP); Yukio Ehara, Konan-shi (JP)

Correspondence Address: DARBY & DARBY P.C., P. O. BOX 5257, NEW YORK, NY, 10150-5257, US

(73) Assignees: Sanyo Electric Co., Ltd., Moriguchi-shi (JP); Sanyo GS Soft Energy Co., Ltd., Kyoto-shi (JP)

(21) Appl. No.: 11/123,579

(22) Filed: May 4, 2005

(30) Foreign Application Priority Data
Jun. 2, 2004 (JP) 2004-164726

(51) Int. Cl. G11C 11/34

(52) U.S. Cl. 365/185.18

(57) ABSTRACT

To provide a high reliability, low cost battery capable of starting discharging or bypassing a charging current in case of overcharge and preventing the battery from becoming unusable. In a battery having a negative terminal attached to a conductive cover plate with an insulator between them, an N-channel field effect transistor is connected between the negative terminal and the cover plate, a source electrode of the N-channel field effect transistor is connected between the negative terminal and the insulator, and a common electrode (drain electrode and gate electrode) is connected to the cover plate.

### CROSS-REFERENCE TO RELATED APPLICATIONS

This non-provisional application claims priority under 35 U.S.C. §119(a) on Patent Application No. 2004-164726 filed in Japan on Jun. 2, 2004, the entire contents of which are hereby incorporated by reference.

### BACKGROUND OF THE INVENTION

The present invention relates to a battery having an N-channel field effect transistor or a P-channel field effect transistor connected between a positive electrode and a negative electrode.

In recent years, the demand for high-performance, small-size and light-weight portable electronic devices is increasing, and, as high-energy density batteries for use in such electronic devices, the use of non-aqueous electrolyte secondary batteries such as lithium ion batteries is expanding. A lithium ion battery is constructed by storing, for example, a power generating element composed of positive and negative plates wound with a separator between them and an electrolyte in a case having a rectangular bottom and side walls and sealing the opening of the case with a rectangular cover plate having a negative terminal.

When the lithium battery is overcharged beyond the specification, for example, a gas is sometimes generated, and therefore a safety valve for emitting the generated gas out of the battery is provided in the cover plate, for example. If the safety valve is activated (ruptured), the battery becomes unusable. Hence, in order to prevent the battery from becoming unusable in case of overcharge, for example, an electronic circuit composed of a an IC (Integrated Circuit) and an FET (Field Effect Transistor), or a switching element which is activated by detecting a temperature, is used to start discharging or bypassing the charging current (see, for example, Japanese Patent Application Laid-Open No. 2000-116011).

However, if a battery uses the switching element which is activated by detecting a temperature, the operation is not stable because it depends on the temperature environment, and thus the battery has the problem of low reliability. On the other hand, if the electronic circuit is used, it is necessary to arrange a plurality of parts on the substrate, and consequently the battery has a problem that the cost and size are increased.

### BRIEF SUMMARY OF THE INVENTION

The present invention has been made with the aim of solving the above problems, and it is an object of the present invention to provide a high reliability, low cost battery capable of preventing the battery from becoming unusable by starting discharging or bypassing a charging current in case of overcharge by connecting the source electrode of an N-channel field effect transistor (hereinafter referred to as the N-channel FET) to a negative electrode and connecting the drain electrode and the gate electrode to a positive electrode.

Another object of the present invention is to provide a battery capable of preventing detachment of an N-channel FET from the battery by connecting the source electrode, or the drain electrode and the gate electrode, of the N-channel FET between an electrode terminal and an insulator.

Still another object of the present invention is to provide a high reliability, low cost battery capable of preventing the battery from becoming unusable by starting discharging or bypassing a charging current in case of overcharge by connecting the source electrode of a P-channel FET to a positive electrode and connecting the drain electrode and the gate electrode to a negative electrode.

Yet another object of the present invention is to provide a battery capable of preventing detachment of a P-channel FET from the battery by connecting the drain electrode and the gate electrode, or the source electrode, of the P-channel FET between an electrode terminal and an insulator.

A battery according to the present invention is characterized by comprising an N-channel field effect transistor connected between a positive electrode and a negative electrode, wherein a source electrode of the N-channel field effect transistor is connected to the negative electrode, and a drain electrode and a gate electrode are connected to the positive electrode.

A battery according to the present invention is a battery comprising: a conductive outer body as a positive electrode; and an electrode terminal as a negative electrode attached to the outer body with an insulator therebetween, and characterized by comprising an N-channel field effect transistor connected between the electrode terminal and the outer body, wherein a source electrode of the N-channel field effect transistor is connected between the electrode terminal and the insulator, and a drain electrode and a gate electrode are connected to the outer body.

A battery according to the present invention is characterized in that the outer body comprises a tube body having a bottom at one end and a covering portion at the end of another side, the electrode terminal is attached to the covering portion with the insulator therebetween, and the drain electrode and the gate electrode of the N-channel field effect transistor are connected to the covering portion.

A battery according to the present invention is a battery comprising: a conductive outer body as a negative electrode; and an electrode terminal as a positive electrode attached to the outer body with an insulator therebetween, and characterized by comprising an N-channel field effect transistor connected between the electrode terminal and the outer body, wherein a drain electrode and a gate electrode of the N-channel field effect transistor are connected between the electrode terminal and the insulator, and a source electrode is connected to the outer body.

A battery according to the present invention is characterized in that the outer body comprises a tube body having a bottom at one end and a covering portion at the end of another side, the electrode terminal is attached to the covering portion with the insulator therebetween, and the source electrode of the N-channel field effect transistor is connected to the covering portion.

A battery according to the present invention is characterized by comprising a P-channel field effect transistor connected between a positive electrode and a negative electrode, wherein a source electrode of the P-channel field effect transistor is connected to the positive electrode, and a drain electrode and a gate electrode are connected to the negative electrode.

A battery according to the present invention is a battery comprising: a conductive outer body as a positive electrode; and an electrode terminal as a negative electrode attached to the outer body with an insulator therebetween, and characterized by comprising a P-channel field effect transistor connected between the electrode terminal and the outer body, wherein a drain electrode and a gate electrode of the P-channel field effect transistor are connected between the electrode terminal and the insulator, and a source electrode is connected to the outer body.

A battery according to the present invention is characterized in that the outer body comprises a tube body having a bottom at one end and a covering portion at the end of another side, the electrode terminal is attached to the covering portion with the insulator therebetween, and the source electrode of the P-channel field effect transistor is connected to the covering portion.

A battery according to the present invention is a battery comprising: a conductive outer body as a negative electrode; and an electrode terminal as a positive electrode attached to the outer body with an insulator therebetween, and characterized by comprising a P-channel field effect transistor connected between the electrode terminal and the outer body, wherein a source electrode of the P-channel field effect transistor is connected between the electrode terminal and the insulator, and a drain electrode and a gate electrode are connected to the outer body.

A battery according to the present invention is characterized in that the outer body comprises a tube body having a bottom at one end and a covering portion at the end of another side, the electrode terminal is attached to the covering portion with the insulator therebetween, and the drain electrode and the gate electrode of the P-channel field effect transistor are connected to the covering portion.

In the present invention, the source electrode of the N-channel FET is connected to the negative electrode, and the drain electrode and the gate electrode are connected to the positive electrode. In the N-channel FET, when the voltage between the source electrode (negative electrode side) and the gate electrode (positive electrode side) exceeds a predetermined value, the resistance between the drain electrode and the source electrode decreases, and the current flows from the drain electrode (positive electrode side) to the source electrode (negative electrode side). Therefore, in an overcharged state in which the charging voltage between a positive electrode and a negative electrode exceeds a predetermined value, discharging from the positive electrode to the negative electrode or bypassing of the charging current is started. By starting discharging or bypassing the charging current in case of overcharge, it is possible to prevent the battery from becoming unusable. Moreover, since the N-channel FET is just connected between the positive electrode and the negative electrode, it is possible to provide a low cost, small-size battery. Further, since the battery does not use a switching element or the like which is activated by detecting a temperature, it does not depend on the temperature environment, and has high reliability.

In the present invention, the source electrode of the N-channel FET is connected between the electrode terminal (negative electrode) and the insulator, and the drain electrode and gate electrode are connected to the outer body (positive electrode). By connecting the source electrode of the N-channel FET between the electrode terminal and the insulator, the source electrode is sandwiched between the electrode terminal and the insulator, and therefore it is possible to prevent detachment of the N-channel FET from the battery. For instance, if the N-channel FET is detached from the battery, it is highly possible that the negative terminal and its periphery are damaged and the battery is unusable, and thus it is possible to prevent the use of the battery from which the N-channel FET is detached. However, in the case where the electrode terminal is the positive electrode and the outer body is the negative electrode, the drain electrode and the gate electrode of the N-channel FET should be connected between the electrode terminal and the insulator, and the source electrode should be connected to the outer body.

In the present invention, the outer body comprises a tube body having a bottom at one end and a covering portion at the end of another side, the drain electrode and the gate electrode of the N-channel field effect transistor are connected to the covering portion (positive electrode) attached to the electrode terminal (negative electrode). However, in the case where the electrode terminal is the positive electrode and the covering portion is the negative electrode, the source electrode of the N-channel FET should be connected to the covering portion. Consequently, the present invention can be applied to conventional batteries easily.

In the present invention, the source electrode of the P-channel FET is connected to the positive electrode, and the drain electrode and the gate electrode are connected to the negative electrode. In the P-channel FET, when the voltage between the gate electrode (negative electrode side) and the source electrode (positive electrode side) exceeds a predetermined value, the resistance between the drain electrode and the source electrode decreases, and the current flows from the source electrode (positive electrode side) to the drain electrode (negative electrode side). Therefore, similarly to the N-channel FET, by starting discharging or bypassing the charging current in case of overcharge, it is possible to prevent the battery from becoming unusable. Moreover, since the P-channel FET is just connected between the positive electrode and the negative electrode, it is possible to provide a low cost, small-size battery. Further, since the battery does not use a switching element or the like which is activated by detecting a temperature, it does not depend on the temperature environment, and has high reliability.

In the present invention, the drain electrode and the gate electrode of the P-channel FET are connected between the electrode terminal (negative electrode) and the insulator, and the source electrode is connected to the outer body (positive electrode). By connecting the drain electrode and the gate electrode of the P-channel FET between the electrode terminal and the insulator, similarly to the above-mentioned case using the N-channel FET, it is possible to prevent detachment of the P-channel FET from the battery, and it is also possible to prevent the use of the battery from which the P-channel FET is detached. However, in the case where the electrode terminal is the positive electrode and the outer body is the negative electrode, the source electrode of the P-channel FET should be connected between the electrode terminal and the insulator, and the drain electrode and the gate electrode should be connected to the outer body.

In the present invention, the outer body comprises a tube body having a bottom at one end and a covering portion at the end of another side, the source electrode of the P-channel field effect transistor is connected to the covering portion (positive electrode) attached to the electrode terminal (negative electrode). However, in the case where the electrode terminal is the positive electrode and the covering portion is the negative electrode, the drain electrode and the gate electrode of the P-channel FET should be connected to the covering portion. Consequently, the present invention can be applied to conventional batteries easily.

The above and further objects and features of the invention will more fully be apparent from the following detailed description with accompanying drawings.

### BRIEF DESCRIPTION OF THE SEVERAL VIEWS OF THE DRAWINGS

FIG. 1 is a perspective view of a battery according to the present invention;

FIG. 2 is an enlarged perspective view of the cover plate of the battery;

FIG. 3 is a cross sectional view cut along the A-A line of FIG. 1;

FIG. 4A is a circuit diagram showing an outline of connection between the power generating element and an FET (N-channel) in the battery;

FIG. 4B is a characteristic view showing the relationship between the source-gate voltage Vgs and the drain-source resistance Rds of the FET;

FIG. 5 is a cross sectional view of essential parts showing a connection example of the negative terminal and the source electrode of the FET; and

FIG. 6 is a circuit diagram showing an outline of connection between a power generating element and an FET (P-channel) in a battery.

### DETAILED DESCRIPTION OF THE INVENTION

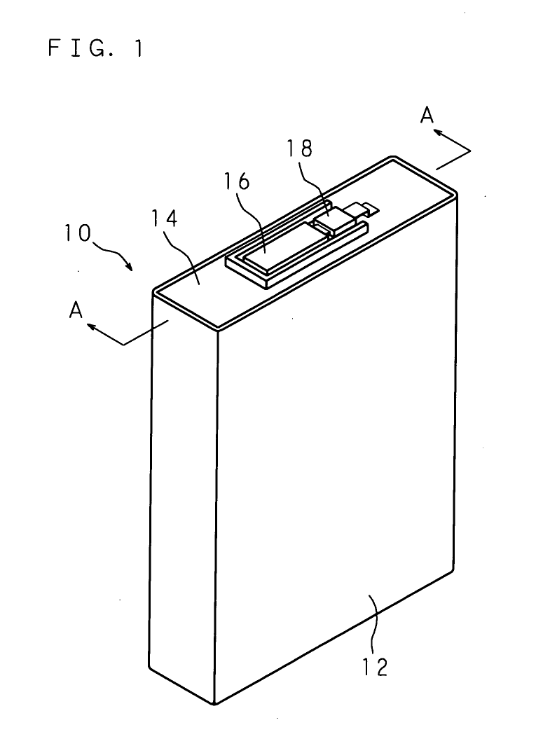

The following description will specifically explain the present invention, based on the drawings illustrating some embodiments thereof. FIG. 1 is a perspective view of a battery according to the present invention. A battery 10 comprises an aluminum case 12 containing a power generating element composed of positive and negative plates wound with a separator between them, and an electrolyte. The aluminum case 12 has a tube body composed of a rectangular bottom and side walls, and an opening to which a rectangular aluminum cover plate 14 having a negative terminal 16 and an FET (Field Effect Transistor) 18 is welded by laser welding.

The positive plate is produced by uniformly applying a positive paste onto an aluminum foil collector with a thickness of 15 μm, for example, and drying and then pressing it by a roll press. The positive paste is prepared by mixing lithium-cobalt complex oxide LiCoO₂ as a positive active material, acetylene black as a conducting assistant, and polyvinylidene fluoride as a binder in a mass ratio of 95:2:3, and adding and stirring a suitable amount of N-methyl-2-pyroridon into the mixture. The positive plate is connected to the inner surface of the case 12, or the inner surface of the cover plate 14, through a positive lead. Thus, the case 12 and cover plate 14 function as the positive terminal.

Meanwhile, the negative plate is produced by applying a negative paste onto both surfaces of a copper foil collector with a thickness of 10 μm, for example, and drying and then pressing it. The negative paste is obtained by adding a suitable amount of N-methyl-2-pyroridon into a negative mixture prepared by mixing graphite (black lead) and polyvinylidene fluoride as a binder in a mass ratio of 90:10. The negative plate is connected to the negative terminal 16 through a negative lead. Note that the negative terminal 16 is insulated from the cover plate 14.

For the separator, a micro-porous polyethylene film is used. For the electrolyte, one obtained by dissolving 1 mol/l of LiPf₆ in a mixed solvent prepared by mixing ethylene carbonate, diethyl carbonate and ethyl methyl carbonate in a volume ratio of 3:5:2 is used. The size of the case 12 is 40 mm in height, 30 mm in width and 5 mm in thickness, for example, and the capacity of the battery 10 is 600 mAh.

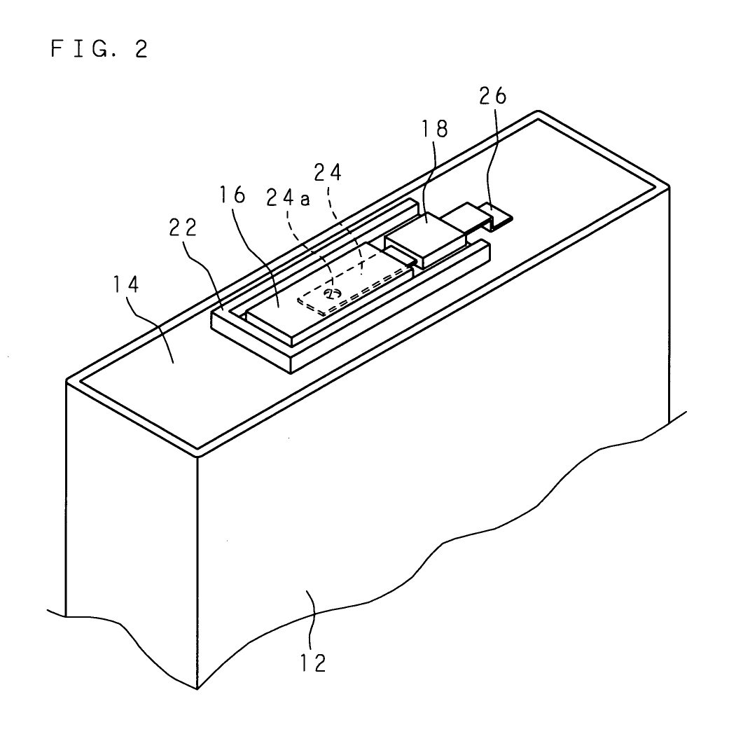

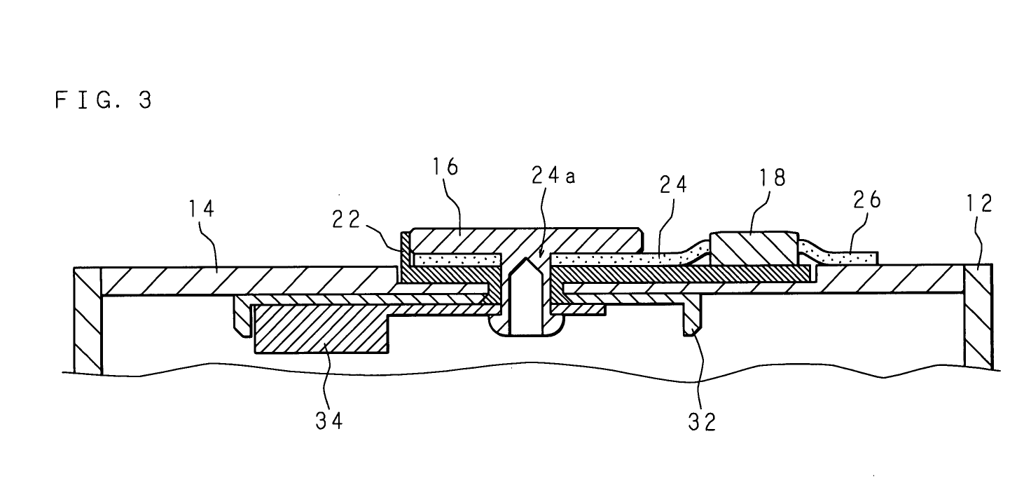

FIG. 2 is an enlarged perspective view of the cover plate 14 of the battery 10. FIG. 3 is a cross sectional view cut along the A-A line of FIG. 1. The FET 18 is an N-channel FET, and comprises a source electrode 24 with a through hole 24a, and a common electrode 26 constructed by connecting a gate electrode and a drain electrode. The negative terminal 16 is in the form of a plate, and has a cylindrical projection at the center of the rear surface. Further, formed in the center of the cover plate 14 is a through hole into which the cylindrical projection of the negative terminal 16 is to be inserted. The projection of the negative terminal 16 is inserted first into the through hole 24a of the source electrode 24 of the FET 18 and then into the through hole of an insulator 22, and thereafter inserted into the through hole of the cover plate 14. The insulator 22 is provided to insulate the negative terminal 16 and the source electrode 24 of the FET 18 from the cover plate 14.

On the projection of the negative terminal 16 inserted into the through hole of the cover plate 14 and projecting from the rear surface of the cover plate 14, first, the through hole of a packing 32 is placed and then the through hole of a negative connecting plate 34 is placed. The negative connecting plate 34 is a metal plate to which the negative lead is connected, and the packing 32 is used to insulate the negative connecting plate 34 from the rear surface of the cover plate 14 and maintain the sealing of the through hole of the cover plate 14. By caulking tightly the end of the projection of the negative terminal 16, the connection between the negative connecting plate 34 and the projection of the negative terminal 16 and the connection between the negative terminal 16 and the source electrode 24 are maintained.

The common electrode 26 of the FET 18 is connected to the front surface of the cover plate 14. For example, if the common electrode 26 is an aluminum alloy, it is possible to weld the common electrode 26 to the front surface of the cover plate 14 by spot welding. If the common electrode 26 is a nickel alloy, for example, it is possible to weld the common electrode 26 to the front surface of the cover plate 14 by using a clad material composed of an aluminum layer and a nickel layer. It is also possible to weld the negative terminal 16 and the source electrode 24 by spot welding, etc.

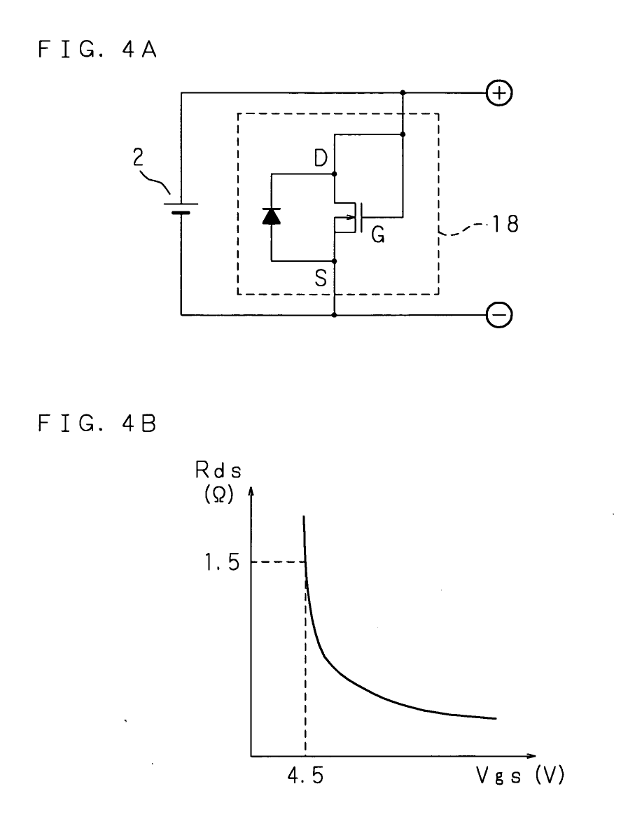

FIG. 4A is a circuit diagram showing an outline of connection between the power generating element 2 and the FET (N-channel) 18 in the battery 10. The source electrode 24 of the FET 18 is connected to the negative terminal 16, the common electrode (drain electrode and gate electrode) 26 of the FET 18 is connected to the cover plate 14 (positive terminal), and, as shown in FIG. 4A, the power generating element 2 and the FET 18 are connected in parallel. Note that, as shown in FIG. 4A, the FET 18 has a diode component whose source side is the anode between the source electrode and the drain electrode.

FIG. 4B is a characteristic view showing the relationship between the source-gate voltage Vgs and the drain-source resistance Rds of the FET 18. As shown in FIG. 4B, when the voltage Vgs exceeds 4.5 V, the resistance Rds decreases abruptly. The normal charging voltage (Vgs) for the battery 10 is 4.2 V, and in an overcharge state in which the charging voltage (Vgs) exceeds 4.5 V, the resistance Rds decreases and discharging of the power generating element 2 or bypassing of the charging current is started. For the voltage (4.5 V) at which the resistance Rds starts to decrease rapidly, it is possible to use an FET of an arbitrary voltage according to the charging voltage.

Table 1 shows the test results obtained by overcharging the battery 10 of the present invention including the FET 18 connected in parallel between a positive electrode and a negative electrode, and a conventional battery connected to a circuit board including an electronic circuit. Note that the conventional battery may include an FET in the circuit board, and in such a case the FET is connected to the battery in series. As the charging conditions, the charging voltage was 10 V, and three types of charging with charging currents of 600 mA, 800 mA and 1000 mA were performed on three same batteries of the present invention and three same conventional batteries for 2.5 hours.

TABLE 1

| CHARGING | THE BATTERY OF THE | CONVENTIONAL |
|---|---|---|
| CONDITION | PRESENT INVENTION | BATTERY |
| 10 V/600 mA | UNUSABLE: 0 | UNUSABLE: 0 |
| 10 V/800 mA | UNUSABLE: 0 | UNUSABLE: 2 |
| 10 V/1000 mA | UNUSABLE: 0 | UNUSABLE: 3 |

As shown in Table 1, when the charging voltage was 10 V and the charging current was 600 mA, the safety valve was not activated in any of the batteries, and none of the batteries became unusable. When the charging voltage was 10 V and the charging current was 800 mA, the safety valve was not activated in any of the batteries 10 of the present invention, and none of the batteries 10 became unusable. However, the safety valve was activated in two of the conventional batteries, and the two conventional batteries became unusable. When the charging voltage was 10 V and the charging current was 1000 mA, the safety valve was not activated in any of the batteries 10 of the present invention, and none of the batteries 10 became unusable. However, the safety valve was activated in every conventional battery, and all the conventional batteries became unusable.

Here, in FIG. 4B, if the voltage Vgs increases and the resistance Rds converges to a minimum value, the drain-source current takes a maximum value, but the rated current that can be passed between the source and the drain of the FET 18 is larger than the maximum value. During normal charging in which the voltage Vgs is smaller than 4.5 V, the resistance Rds is sufficiently high, discharge due to a leakage current between the drain and the source is extremely small, and there is almost no decrease in the capacity of the battery 10 due to the parallel connection of the FET 18 and the power generating element 2.

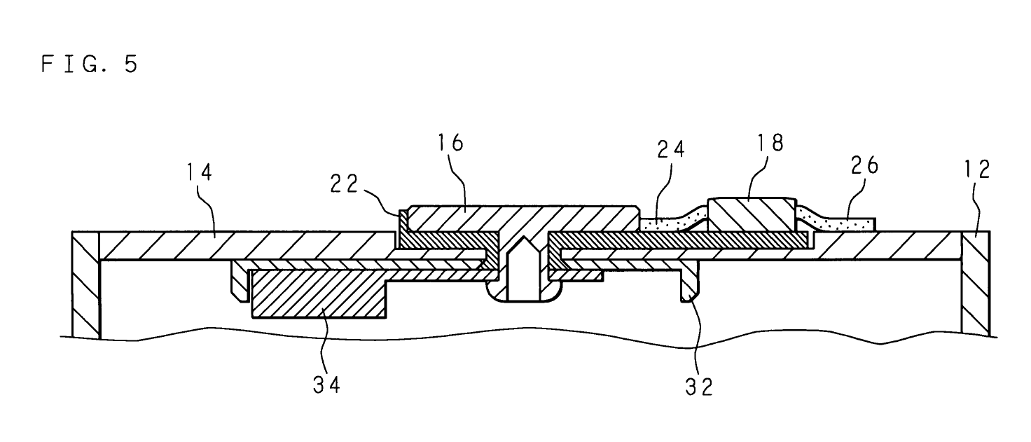

In the above-described embodiment, although the source electrode 24 of the FET 18 is connected between the negative terminal 16 and the insulator 22, it is also possible to connect the source electrode 24 to the negative terminal 16 on the insulator 22. FIG. 5 is a cross sectional view of essential parts showing a connection example of the negative terminal 16 and the source electrode 24 of the FET 18. The insulator 22 is placed between the negative terminal 16 and the cover plate 14, the FET 18 and the source electrode 24 are positioned on the insulator 22, and an end of the source electrode 24 is connected to the negative terminal 16. For example, if the negative terminal 16 and the source electrode 24 are made of an nickel alloy, it is possible to weld the end of the source electrode 24 to the negative terminal 16 by spot welding.

However, when the end of the source electrode 24 is connected to the negative terminal 16 on the insulator 22 as shown in FIG. 5, it is relatively easy to intentionally detach the FET 18 from the battery 10. Moreover, it is highly possible that the battery 10 may be used in a state in which the FET 18 is detached. On the other hand, as shown in FIG. 3, when the source electrode 24 is sandwiched between the negative terminal 16 and the insulator 22, it is difficult to intentionally detach the FET 18 from the battery 10. In particular, when the projection of the negative terminal 16 is inserted into the through hole 24a of the source electrode 24, it is extremely difficult to intentionally detach the FET 18 from the battery 10. For instance, if the FET 18 is detached, the negative terminal 16 is detached and the sealing performance for the through hole of the cover plate 14 is decreased, and thus it is very unlikely that the battery 10 may be used. It is therefore possible to prevent the use of the battery 10 which has lost the function of discharging or bypassing the charging current in case of overcharge due to detachment of the FET 18.

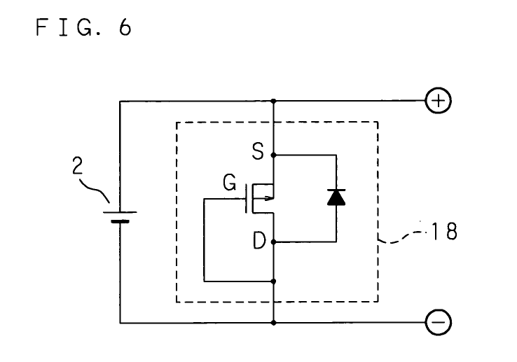

Each of the above-described embodiments is explained by illustrating the N-channel FET as an example, but it is of course possible to use a P-channel FET. FIG. 6 is a circuit diagram showing an outline of connection between the power generating element 2 and the FET (P-channel) 18 in a battery 10. The common electrode (drain electrode and gate electrode) 26 of the FET 18 is connected to the negative terminal 16, the source electrode 24 of the FET 18 is connected to the cover plate 14 (positive terminal), and the power generating element 2 and the FET 18 are connected in parallel. In this case, as shown in FIG. 6, the FET 18 has a diode component whose drain side is the anode between the source electrode and the drain electrode. Further, a through hole is formed in the common electrode 26. In case of overcharge, the voltage Vgs increases and the resistance Rsd decreases, and discharging of the power generating element 2 or bypassing of the charging current is started.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. A battery comprising:
an N-channel field effect transistor connected between a positive electrode and a negative electrode, wherein
a source electrode of the N-channel field effect transistor is connected to the negative electrode, and a drain electrode and a gate electrode of the N-channel field effect transistor are connected to the positive electrode.

2. The battery according to claim 1, further comprising:
a conductive outer body as the positive electrode;
an electrode terminal as the negative electrode; and
an insulator disposed between the conductive outer body and the electrode terminal, wherein
the source electrode of the N-channel field effect transistor is connected between the electrode terminal and the insulator, and the drain electrode and the gate electrode of the N-channel field effect transistor are connected to the conductive outer body.

3. The battery according to claim 2, wherein
the conductive outer body comprises a tube body having a bottom at one end and a covering portion at the end of another side;
the electrode terminal is attached to the covering portion with the insulator disposed between the electrode terminal and the covering portion, and
the drain electrode and the gate electrode of the N-channel field effect transistor are connected to the covering portion.

4. The battery according to claim 1, further comprising:
a conductive outer body as the negative electrode;
an electrode terminal as the positive electrode; and
an insulator disposed between the conductive outer body and the electrode terminal, wherein
the drain electrode and the gate electrode of the N-channel field effect transistor are connected between the electrode terminal and the insulator, and the source electrode of the N-channel field effect transistor is connected to the conductive outer body.

5. The battery according to claim 4, wherein
the conductive outer body comprises a tube body having a bottom at one end and a covering portion at the end of another side,
the electrode terminal is attached to the covering portion with the insulator disposed between the electrode terminal and the covering portion, and
the source electrode of the N-channel field effect transistor is connected to the covering portion.

6. A battery comprising:
a P-channel field effect transistor connected between a positive electrode and a negative electrode, wherein
a source electrode of the P-channel field effect transistor is connected to the positive electrode, and a drain electrode and a gate electrode of the P-channel field effect transistor are connected to the negative electrode.

7. The battery according to claim 6, comprising:
a conductive outer body as the positive electrode;
an electrode terminal as the negative electrode; and
an insulator disposed between the conductive outer body and the electrode terminal, wherein
the drain electrode and the gate electrode of the P-channel field effect transistor are connected between the electrode terminal and the insulator, and the source electrode of the P-channel field effect transistor is connected to the conductive outer body.

8. The battery according to claim 7, wherein
the conductive outer body comprises a tube body having a bottom at one end and a covering portion at the end of another side,
the electrode terminal is attached to the covering portion with the insulator disposed between the electrode terminal and the covering portion, and
the source electrode of the P-channel field effect transistor is connected to the covering portion.

9. The battery according to claim 6, comprising:
a conductive outer body as the negative electrode;
an electrode terminal as the positive electrode; and
an insulator disposed between the conductive outer body and the electrode terminal, wherein
the source electrode of the P-channel field effect transistor is connected between the electrode terminal and the insulator, and the drain electrode and the gate electrode of the P-channel field effect transistor are connected to the conductive outer body.

10. The battery according to claim 9, wherein
the conductive outer body comprises a tube body having a bottom at one end and a covering portion at the end of another side,
the electrode terminal is attached to the covering portion with the insulator disposed between the electrode terminal and the covering portion, and
the drain electrode and the gate electrode of the P-channel field effect transistor are connected to the covering portion.
